(19) United States
(12) Patent Application Publication
(10) Pub. No.: US 2026/0033012 A1
(43) Pub. Date: Jan. 29, 2026

(54) SEMICONDUCTOR INTEGRATED CIRCUIT DEVICE

(71) Applicant: Socionext Inc., Kanagawa (JP)

(72) Inventor: Toshihiro NAKAMURA, Yokohama-shi (JP)

(21) Appl. No.: 19/343,894

(22) Filed: Sep. 29, 2025

Related U.S. Application Data
(63) Continuation of application No. PCT/JP2024/014151, filed on Apr. 5, 2024.

(30) Foreign Application Priority Data
Apr. 13, 2023 (JP) 2023-065689

(51) Int. Cl. H10D 89/60

(52) U.S. Cl. CPC H10D 89/611

(57) ABSTRACT

In a semiconductor integrated circuit device, an output transistor part including a transistor connected between VSS and an output terminal includes an active region having a nanosheet as a channel. A power line and an output line are placed in an interconnect layer on the back side of the transistor so as to overlap the active region in planar view. The power line is connected to the lower face of a portion that is to be the source of the active region through a via, and the output line is connected to the lower face of a portion that is to be the drain of the active region.

### CROSS-REFERENCE TO RELATED APPLICATIONS

This is a continuation of International Application No. PCT/JP2024/014151 filed on April 5, 2024, which claims priority to Japanese Patent Application No. 2023-065689 filed on April 13, 2023. The entire disclosures of these applications are incorporated by reference herein.

### BACKGROUND

The present disclosure relates to a semiconductor integrated circuit device, and more particularly to a layout configuration of an IO cell including an input/output circuit for exchanging signals with the outside of the semiconductor integrated circuit device.

The IO cell, constituting a semiconductor integrated circuit device, for exchanging signals with the outside of the semiconductor integrated circuit device is generally provided with an output buffer and an electrostatic discharge (ESD) protection circuit. Also, with the recent miniaturization of the semiconductor integrated circuit device, demands for speedup are increasingly growing.

US Patent Application Publication No. 2021/0375853 discloses, for higher integration of a semiconductor integrated circuit device, a technique of providing interconnects in the backside portion of the substrate right under transistors and connecting the sources/drains of the transistors to these interconnects.

The cited patent document however does not disclose a specific layout structure about a circuit that passes a large current, like an output circuit in an input/output circuit, in the configuration where interconnects are provided right under transistors. Also, the cited patent document does not disclose a specific layout structure about an ESD protection circuit.

An objective of the present disclosure is presenting specific layout structures about a circuit that passes a large current and an ESD protection circuit in a semiconductor integrated circuit device having a configuration in which interconnects are laid right under transistors.

### SUMMARY

According to the first mode of the disclosure, a semiconductor integrated circuit device includes: a first output transistor part including a first transistor of a first conductivity type connected between a first power supply supplying a first power supply voltage and an output terminal; a first power line supplying the first power supply voltage; and an output line connected to the output terminal, wherein the first output transistor part includes a first active region of the first conductivity type forming a channel, source, and drain of the first transistor, and having a nanosheet as the channel, the first power line is placed in an interconnect layer located on a back side of the first transistor so as to overlap the first active region in planar view, and connected to a lower face of a portion that is to be the source of the first transistor in the first active region through a via, and the output line is placed in the same interconnect layer as the first power line so as to overlap the first active region in planar view, and connected to a lower face of a portion that is to be the drain of the first transistor in the first active region through a via.

According to the above mode, the first output transistor part including the first transistor connected between the first power supply and the output terminal has a first active region forming the channel, source, and drain of the first transistor. The first active region has a nanosheet as the channel. The first power line and the output line are placed in an interconnect layer on the back side of the first transistor so as to overlap the first active region in planar view. The first power line is connected to the lower face of a portion that is the source of the first transistor in the first active region through a via, and the output line is connected to the lower face of a portion that is to be the drain of the first transistor in the first active region through a via. It is therefore possible to pass a large current to the output terminal without the need to widen the layout area.

According to the second mode of the disclosure, a semiconductor integrated circuit device includes: an electrostatic discharge (ESD) protection diode connected between a first power supply supplying a first power supply voltage and an output terminal; a first power line supplying the first power supply voltage; and an output line connected to the output terminal, wherein the ESD protection diode includes a first active region of a first conductivity type constituting one terminal out of an anode and a cathode, and having a first nanosheet, and a second active region of a second conductivity type constituting the other terminal out of the anode and the cathode, and having a second nanosheet, the first power line is placed in an interconnect layer located on a back side of the first and second active regions so as to overlap the first active region in planar view, and connected to lower faces of portions sandwiching the first nanosheet in the first active region through vias, and the output line is placed in the same interconnect layer as the first power line so as to overlap the second active region in planar view, and connected to lower faces of portions sandwiching the second nanosheet in the second active region through vias.

According to the above mode, the ESD protection diode connected between the first power supply and the output terminal includes: a first active region of the first conductivity type constituting one terminal out of the anode and the cathode; and a second active region of the second conductivity type constituting the other terminal out of the anode and the cathode. The first and second active regions have nanosheets. The first power line and the output line are placed in an interconnect layer on the back side of the first and second active regions. The first power line is connected to lower faces of portions sandwiching the nanosheet in the first active region through vias, and the output line is connected to lower faces of portions sandwiching the nanosheet in the second active region through vias. It is therefore possible to improve the characteristics and performance of the ESD protection diode without the need to widen the layout area.

According to the third mode of the disclosure, a semiconductor integrated circuit device includes: a first output transistor part including a first transistor of a first conductivity type connected between a first power supply supplying a first power supply voltage and a first node; a protective resistance connected between an output terminal and the first node; and a first power line supplying the first power supply voltage, wherein the first output transistor part includes a first active region of the first conductivity type forming a channel, source, and drain of the first transistor, and having a nanosheet as the channel, the first power line is placed in an interconnect layer located on a back side of the first transistor so as to overlap the first active region in planar view, and connected to a lower face of a portion that is to be the source of the first transistor in the first active region through a via, and the protective resistance is formed in a layer above the first active region, and is connected to a portion that is to be the drain of the first transistor in the first active region at one end and to an output line connected to the output terminal at the other end.

According to the above mode, the first output transistor part including the first transistor connected between the first power supply and the first node has a first active region forming the channel, source, and drain of the first transistor. The first active region has a nanosheet as the channel. The first power line is placed in an interconnect layer on the back side of the first transistor, and connected to the lower face of a portion that is the source of the first transistor in the first active region through a via. The resistor element connected between the output terminal and the first node is formed in a layer above the first active region, and is connected to a portion that is to be the drain of the first transistor in the first active region at one end and to an output line connected to the output terminal at the other end. It is therefore possible to pass a large current to the output terminal without the need to widen the layout area.

According to the present disclosure, in a semiconductor integrated circuit device having a configuration in which interconnects are laid right under transistors, a circuit that passes a large current and an ESD protection circuit can be implemented in a small area.

### BRIEF DESCRIPTION OF THE DRAWINGS

FIG. 1 is a plan view schematically showing the entire configuration of a semiconductor integrated circuit device according to an embodiment.

FIG. 2 is a circuit configuration diagram of an output circuit according to the first embodiment.

FIG. 3 shows an overview example of an IO cell layout in the first embodiment.

FIG. 4 is a plan view showing a layout of an output transistor N1 in FIG. 3.

FIG. 5 is a plan view showing the layout of the output transistor N1 in FIG. 3.

FIGS. 6A and 6B are cross-sectional views of the layout in FIGS. 4 and 5.

FIGS. 7A and 7B show another configuration example of the semiconductor integrated circuit device according to the embodiment.

FIG. 8 is a plan view showing a layout of an output transistor P1 in FIG. 3.

FIG. 9 is a plan view showing the layout of the output transistor P1 in FIG. 3.

FIG. 10 is a plan view showing a layout of a diode 1a in FIG. 3.

FIG. 11 is a plan view showing the layout of the diode 1a in FIG. 3.

FIGS. 12A and 12B are cross-sectional views of the layout in FIGS. 10 and 11.

FIG. 13 is a plan view showing a layout of a diode 1b in FIG. 3.

FIG. 14 is a plan view showing the layout of the diode 1b in FIG. 3.

FIG. 15 is a circuit configuration diagram of an output circuit according to the second embodiment.

FIG. 16 shows an overview example of an IO cell layout in the second embodiment.

FIG. 17 is a plan view showing a layout of an output transistor N1 in FIG. 16.

FIG. 18 is a plan view showing the layout of the output transistor N1 in FIG. 16.

FIG. 19 is a plan view showing a layout of an output transistor P1 in FIG. 16.

FIG. 20 is a plan view showing the layout of the output transistor P1 in FIG. 16.

FIG. 21 is a plan view showing a layout of a diode 1a in FIG. 16.

FIG. 22 is a plan view showing a layout of a diode 1b in FIG. 16.

FIG. 23 is a circuit configuration diagram of an output circuit according to an alteration of the second embodiment.

FIG. 24 shows an overview example of an IO cell layout in the alteration of the second embodiment.

### DETAILED DESCRIPTION

Embodiments of the present disclosure will be described hereinafter with reference to the accompanying drawings. In the following description, “VDDIO” and “VSS” denote power supply voltages or power supplies themselves. Also, transistors are formed on a P-substrate or an N-well. Note however that transistors may be formed on a P-well or formed on an N-substrate.

### First Embodiment

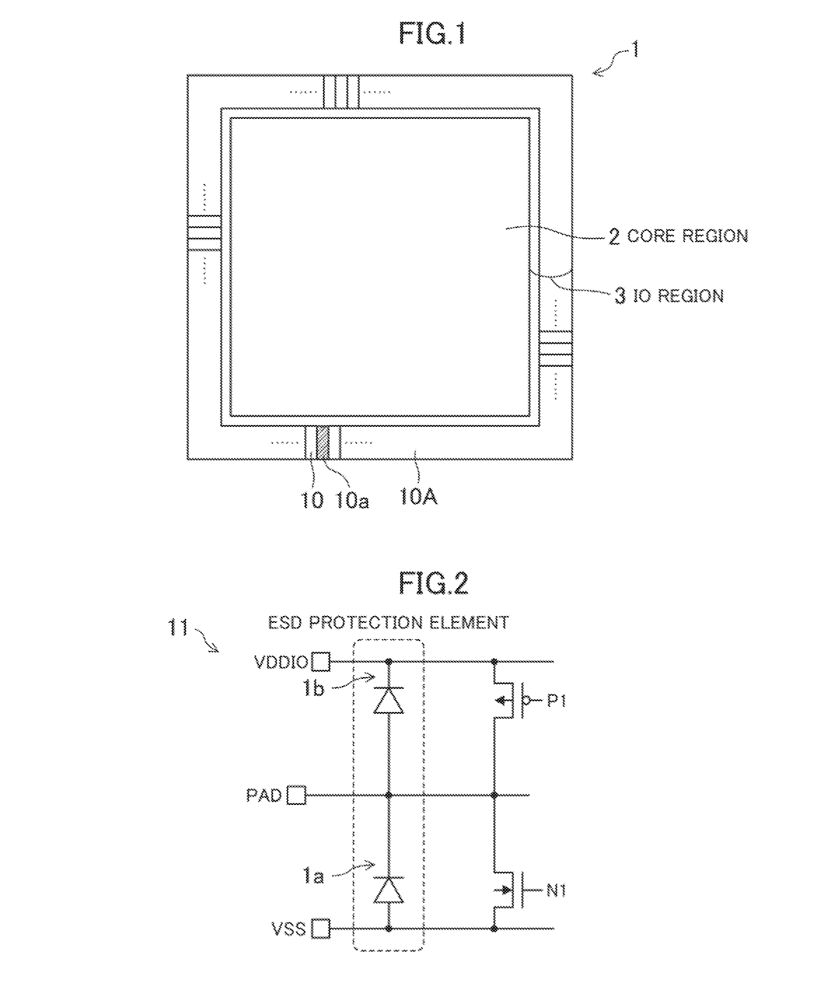

FIG. 1 is a plan view schematically showing the entire configuration of a semiconductor integrated circuit device according to an embodiment. The semiconductor integrated circuit device 1 shown in FIG. 1 includes: a core region 2 in which internal core circuits are formed; and an IO region 3 provided between the core region 2 and the chip edges, in which interface circuits (IO circuits) are formed. An IO cell row 10A is provided in the IO region 3 to encircle the peripheral portion of the semiconductor integrated circuit device 1. Although illustration is simplified in FIG. 1, a plurality of IO cells 10 constituting the interface circuits are arranged in line in the IO cell row 10A. Also, although illustration is omitted in FIG. 1, a plurality of external connection pads are placed in the semiconductor integrated circuit device 1. The external connection pads are provided on the back side of a semiconductor chip. Note that the IO cell row 10A may be provided partly in the peripheral portion of the semiconductor integrated circuit device 1.

The IO cells 10 include signal IO cells and power IO cells. The signal IO cells include circuits required for exchanging signals with the outside of the semiconductor integrated circuit device 1 or with the core region 2, such as a level shifter circuit, an output buffer circuit, and a circuit for ESD protection. The power IO cells, which supply power fed to the external connection pads to the inside of the semiconductor integrated circuit device 1, include a circuit for ESD protection, for example.

FIG. 2 is a circuit configuration diagram of an output circuit 11 included in the IO cell 10. Note that, although an actual output circuit includes circuit elements other than those shown in FIG. 2, such elements are omitted in FIG. 2.

The output circuit 11 shown in FIG. 2 includes an external output terminal PAD, output transistors P1 and N1, and electrostatic discharge (ESD) protection diodes 1a and 1b. The output transistor P1 is a p-type transistor and the output transistor N1 is an n-type transistor.

The output transistors P1 and N1 output signals to the external output terminal PAD in response to signals received at their gates. The output transistor P1 is connected to VDDIO at its source and to the external output terminal PAD at its drain. The output transistor N1 is connected to VSS at its source and to the external output terminal PAD at its drain.

The ESD protection diode 1a is provided between VSS and the external output terminal PAD, with its anode connected to VSS and its cathode connected to the external output terminal PAD. The ESD protection diode 1b is provided between VDDIO and the external output terminal PAD, with its anode connected to the external output terminal PAD and its cathode connected to VDDIO. When high-voltage noise is input into the external output terminal PAD, a current flows to VDDIO and VSS through the ESD protection diodes 1a and 1b, whereby the output transistors P1 and N1 are protected.

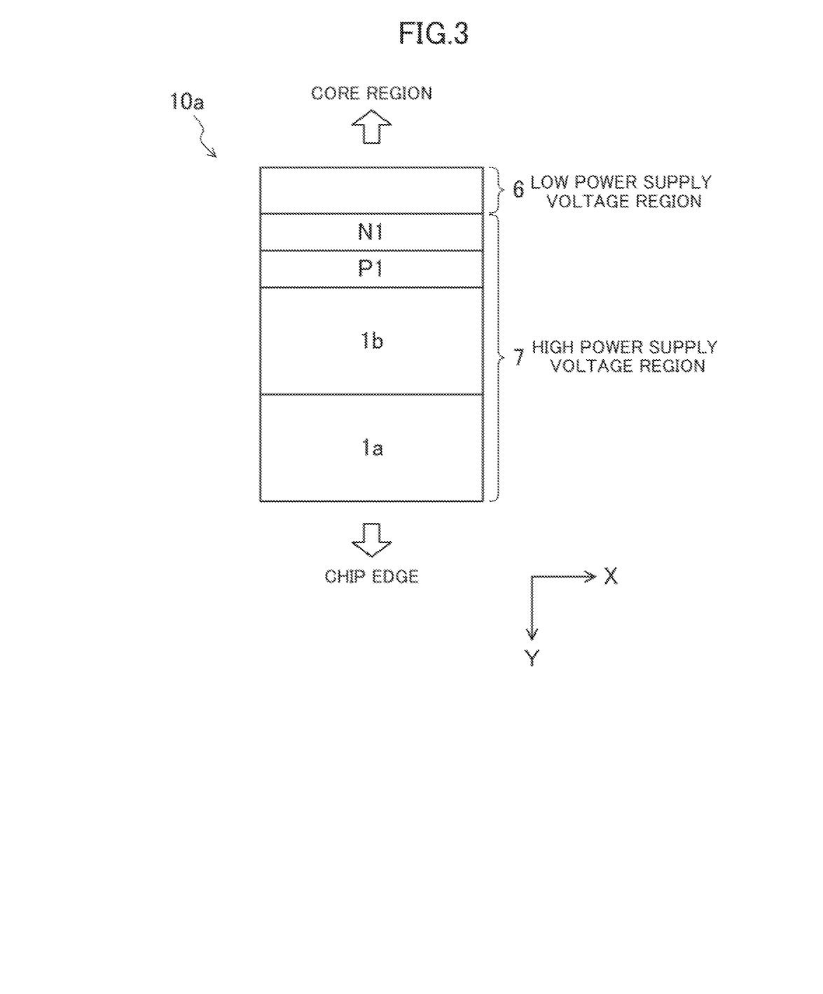

FIG. 3 shows an overview example of the layout of an IO cell. The layout of FIG. 3 corresponds to an IO cell 10a, one of the IO cells 10 arranged along the lower edge of the semiconductor integrated circuit device 1 in FIG. 1. Note herein that the X direction (corresponding to the first direction) is the direction along an outer edge of the semiconductor integrated circuit device 1, along which a plurality of IO cells 10 are arranged, and the Y direction (corresponding to the second direction) is the direction perpendicular to the X direction.

The IO cell generally includes: a high power supply voltage region including a circuit for ESD protection and an output buffer for outputting a signal to the outside of the semiconductor integrated circuit device; and a low power supply voltage region including a circuit for inputting/outputting a signal into/from the inside of the semiconductor integrated circuit device. The IO cell 10a of FIG. 3 has a low power supply voltage region 6 and a high power supply voltage region 7 separated from each other in the Y direction. The low power supply voltage region 6 is located closer to the core region 2, and the high power supply voltage region 7 is located closer to the chip edge.

The low power supply voltage region 6, located near the output transistors N1 and P1, includes a circuit that generates signals input into the gates of the output transistors N1 and P1, for example.

The IO cell 10a shown in FIG. 3 constitutes the output circuit 11 of FIG. 2. In the high power supply voltage region 7, the ESD protection diode 1a, the ESD protection diode 1b, the output transistor P1, and the output transistor N1 are arranged in this order from the chip edge. The order of arrangement of the ESD protection diodes 1a and 1b and the output transistors P1 and N1 is not limited to that shown in FIG. 3. For example, the positions of the output transistor P1 and the output transistor N1 may be changed with each other, and the positions of the ESD protection diode 1a and the ESD protection diode 1b may be changed with each other.

### Output Transistor N1

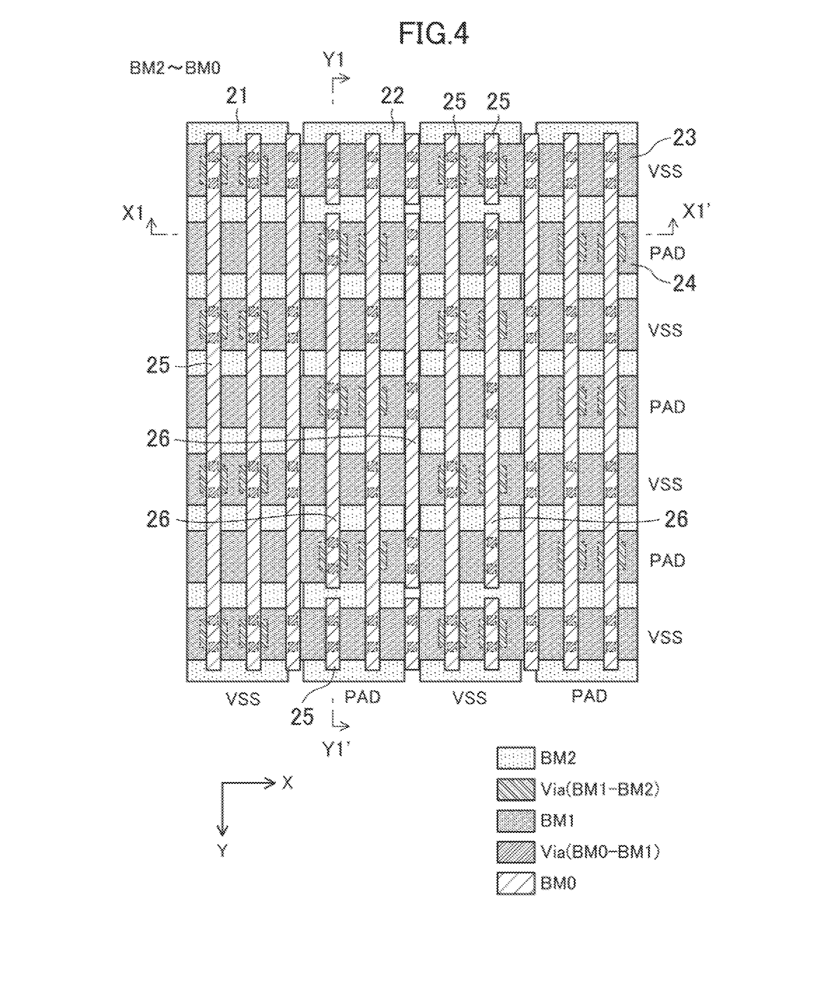

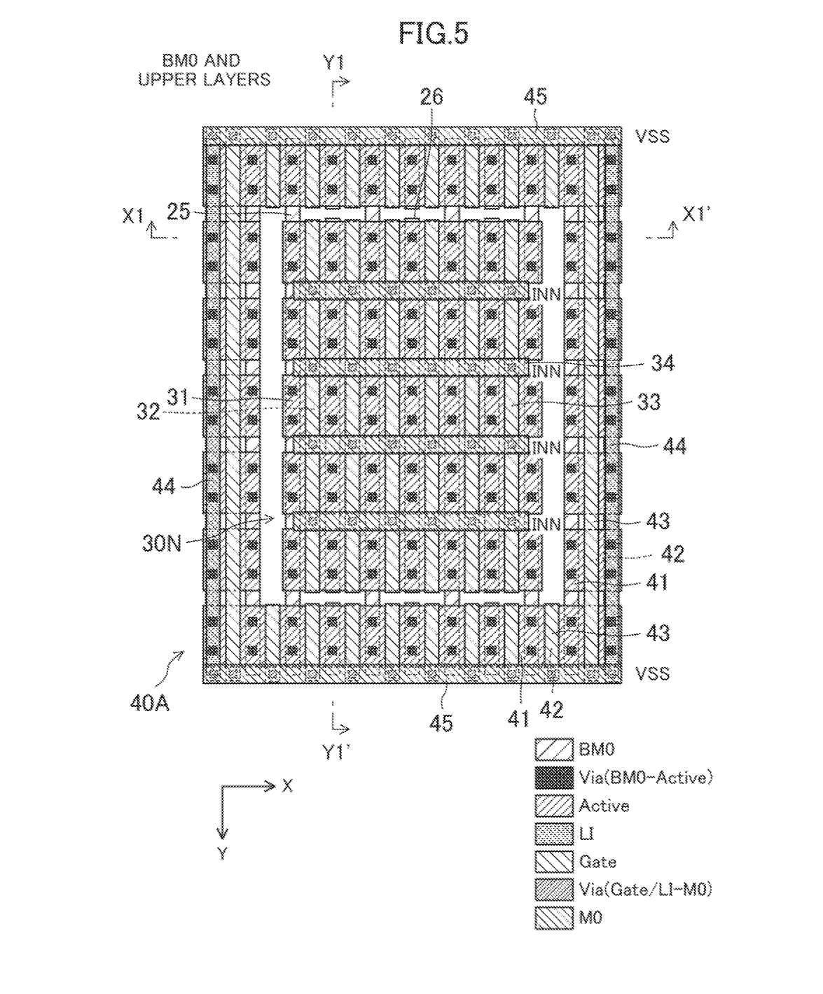

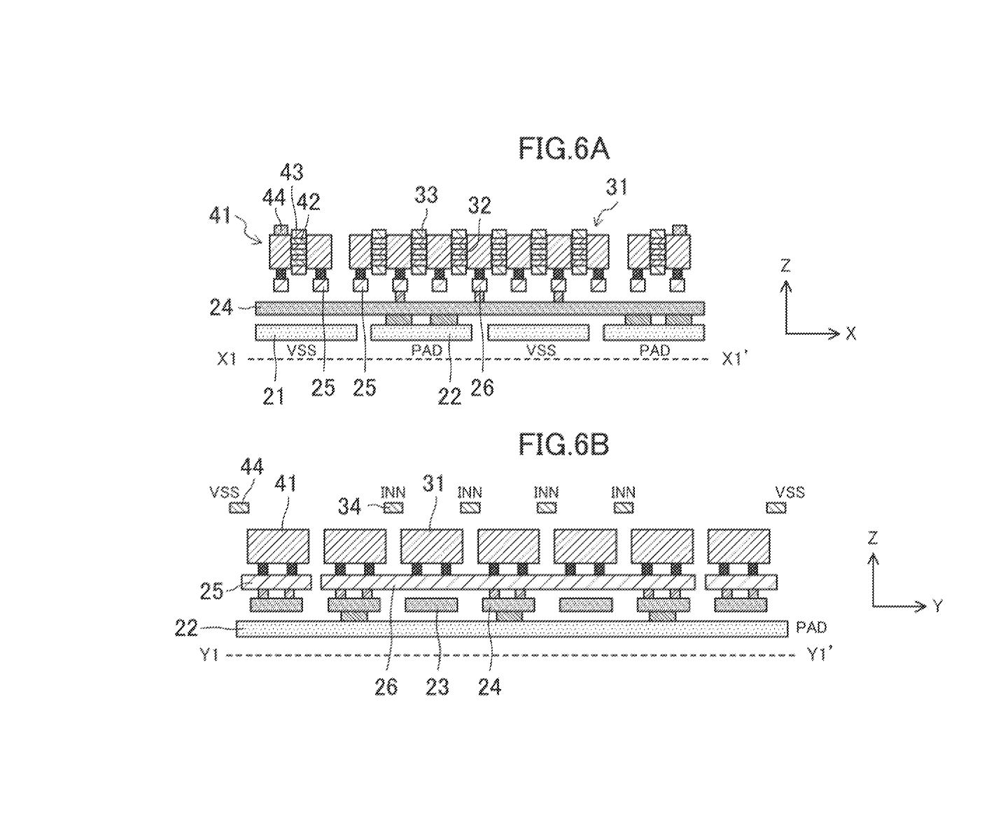

FIGS. 4 and 5 are plan views showing details of the layout of the output transistor N1 in FIG. 3. FIG. 4 shows a structure of a backside metal 0 (BM0) layer, a backside metal 1 (BM1) layer, and a backside metal 2 (BM2) layer that are interconnect layers provided in the backside portion of the semiconductor chip in which transistors are formed. The BM1 layer is located below the BM0 layer, i.e., located farther from the transistors, and the BM2 layer is located below the BM1 layer, i.e., located still farther from the transistors. FIG. 5 shows a structure of the BM0 layer and layers above the BM0 layer. FIGS. 6A-6B are cross-sectional views of the layout of FIGS. 4 and 5, where FIG. 6A shows a cross-sectional structure taken along line X1-X1’ and FIG. 6B shows a cross-sectional structure taken along line Y1-Y1’. Note that the direction normal to the substrate plane is indicated as the Z direction.

As shown in FIG. 5, an output transistor part 30N is formed in the center of the figure, and an guard ring part 40A is formed in a ring shape around the output transistor part 30N.

As shown in FIG. 4, in the BM2 layer, power lines 21 and output lines 22 extending in the Y direction are placed. The power lines 21 supply the power supply voltage VSS, and the output lines 22 are connected to the external output terminal PAD. The power lines 21 and the output lines 22 are placed with the minimum spacing among them under constraints in the manufacturing processes.

In the BM1 layer, power lines 23 and output lines 24 extending in the X direction are placed. The power lines 23 are connected to the power lines 21 in the BM2 layer through vias, and the output lines 24 are connected to the output lines 22 in the BM2 layer through vias. The power lines 23 and the output lines 24 are placed with the minimum spacing among them under constraints in the manufacturing processes.

In the BM0 layer, power lines 25 and output lines 26 extending in the Y direction are placed. The power lines 25 are connected to the power lines 23 in the BM1 layer through vias. The power lines 25 are formed in the guard ring part 40A and also formed to pass through the output transistor part 30N. The output lines 26 are connected to the output lines 24 in the BM1 layer through vias. The output lines 26 are formed in the output transistor part 30N.

In the output transistor part 30N, n-type active regions 31 extending in the X direction are formed. The active region is a region forming the channel, source, and drain of a transistor. The active region constituting a nanosheet FET has a nanosheet as the channel. In the active region, portions that are to be the source and the drain on both sides of a nanosheet are formed by epitaxial growth from the nanosheet, for example. As will be described later, however, there is a case where the active region does not constitute a transistor.

In FIG. 5, five active regions 31 are arranged in the Y direction to constitute the transistor N1, and each active region 31 includes six nanosheets 32. Each nanosheet 32 has a structure of three sheets lying one above another and extends in the X direction.

In the active regions 31, portions that are to be the sources of transistors overlap the power lines 25 in the BM0 layer in planar view and are connected to the power lines 25 through vias. In the active regions 31, portions that are to be the drains of the transistors overlap the output lines 26 in the BM0 layer in planar view and are connected to the output lines 26 through vias.

Over the five active regions 31, gate interconnects 33 extending in the Y direction are formed. The gate interconnects 33 surround the peripheries of the nanosheets 32 in the Y direction and the Z direction through gate insulating films (not shown). The gate interconnects 33 correspond to the gate of the transistor N1.

In an M0 layer that is a metal interconnect layer located above the transistors, signal lines 34 extending in the X direction are formed. The signal lines 34 are connected to the gate interconnects 33 in the output transistor part 30N through vias. The signal lines 34 supply a signal INN to the gate of the transistor N1.

In the guard ring part 40A, p-type active regions 41 are formed. The active regions 41 include nanosheets 42. Each nanosheet 42 has a structure of three sheets lying one above another and extends in the X direction. The active regions 41 however do not function as transistors.

In the active regions 41, portions sandwiching the nanosheets 42 (portions corresponding to the sources and drains of transistors) overlap the power lines 25 in the BM0 layer and are connected to the power lines 25 through vias. That is, the active regions 41 supply the power supply voltage VSS supplied from the power lines 25 to the P-substrate or the P-well. Also, the guard ring part 40A serves to prevent or reduce propagation of noise between the output transistor part 30N and transistors and the like around this part and occurrence of latch-up.

Also, in the active regions 41, gate interconnects 43 extending in the Y direction are formed. The gate interconnects 43 surround the peripheries of the nanosheets 42 in the Y direction and the Z direction through gate insulating films (not shown). The gate interconnects 43 however do not function as gates of transistors.

Local interconnects (LI) 44 extending in the Y direction are placed. The local interconnects 44 are formed on the upper faces of the active regions 41. In the M0 layer, power lines 45 extending in the X direction are placed. The power lines 45 are connected to the local interconnects 44 and also connected to the gate interconnects 43. Thus, the power supply voltage VSS is supplied to the gate interconnects 43 in the guard ring part 40A.

Having the configuration described above, the following effects are obtained. Only the VSS-supply power lines and the output lines connected to the external output terminal PAD are placed as the interconnects formed on the back side of the transistors. Also, in the BM1 layer and the BM2 layer, the power lines and the output lines are laid to the maximum extent. It is therefore possible to pass a large current and also reduce interconnect resistance.

Also, the power lines and the output lines in the BM0 layer are connected to the active regions 31 constituting the output transistor N1 only through vias. It is therefore possible to reduce the resistance value and thus pass a large current.

As described above, the output transistor part 30N including the transistor N1 connected between the power supply VSS and the external output terminal PAD has the active regions 31 forming the channel, source, and drain of the transistor N1. The active regions 31 have the nanosheets 32 as the channel. The power lines 25 and the output lines 26 are placed in the interconnect layer on the back side of the transistor N1 so as to overlap the active regions 31. The power lines 25 are connected to the lower faces of the portions that are to be the source of the transistor N1 in the active regions 31 through vias, and the output lines 26 are connected to the lower faces of the portions that are to be the drain of the transistor N1 through vias. It is therefore possible to pass a large current to the output terminal without the need to widen the layout area.

While the power lines 21, 23, and 25 and the output lines 22, 24, and 26 are formed in the interconnect layers provided in the backside portion of the semiconductor chip, the configuration is not limited to this. In the present disclosure, it is only required to form the power lines and the output lines on the back side of the transistors (active regions). The back side of the transistors as used herein refers to the side, with respect to the transistors, opposite to the side on which the local interconnects and the metal interconnects connected to the transistors are stacked one upon another.

The power lines 21, 23, and 25 and the output lines 22, 24, and 26 may be formed in a plurality of interconnect layers.

Moreover, an interconnect layer may be formed further below the BM2 layer to form backside lines. In this case, it is preferable to change the directions in which the lines extend alternately, such as that lines extend in the X direction in a BM3 layer and extend in the Y direction in a BM4 layer, for example.

### Another Configuration Example

The power lines and the output lines formed on the back side of the transistors described above may be formed using a semiconductor chip other than the semiconductor chip in which the transistors are formed.

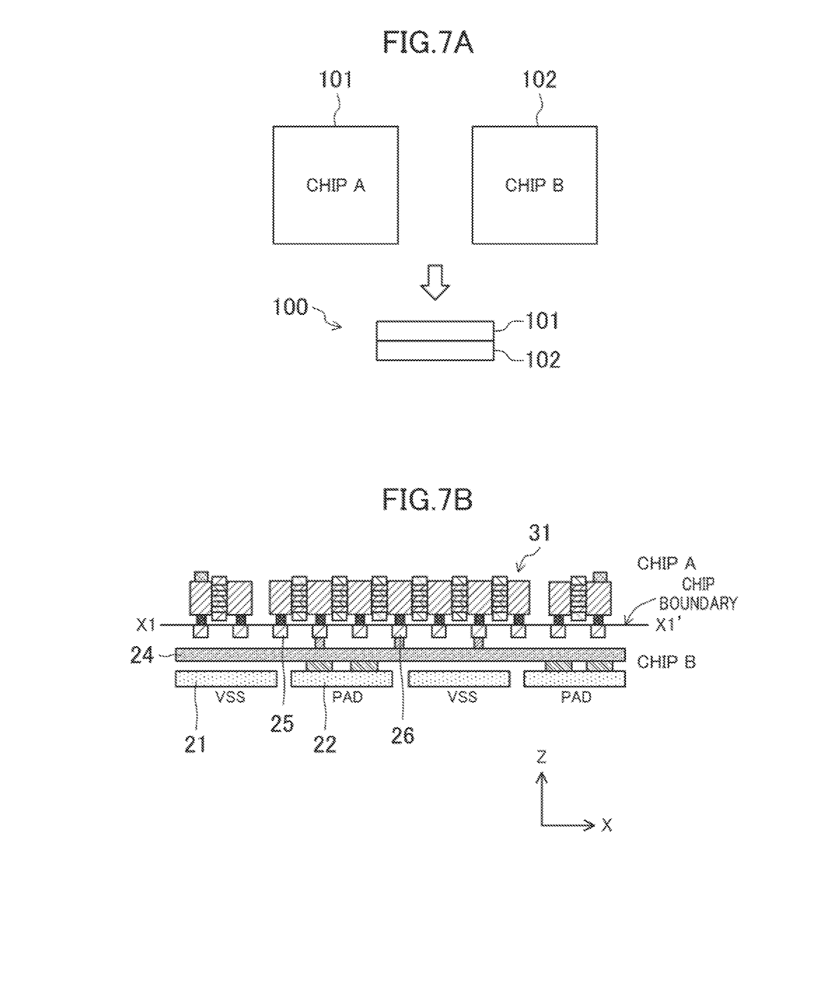

FIG. 7A shows another configuration example of the semiconductor integrated circuit device according to the embodiment. A semiconductor integrated circuit device 100 shown in FIG. 7A is constituted by a first semiconductor chip 101 (chip A) and a second semiconductor chip 102 (chip B) stacked one upon the other. In the chip A, the above-described IO cells and the like are placed. In the chip B, the power lines and the output lines are formed in interconnect layers provided on the surface. The chip B is bonded to the back of the chip A using bumps and the like.

FIG. 7B shows a cross section in this configuration example taken along line X1-X1’ of the layout in FIGS. 4 and 5. As shown in FIG. 7B, the VSS-supply power lines and the output lines connected to the external output terminal PAD are formed in the interconnect layers provided on the surface of the chip B. The power lines 25 in the BM0 layer are connected to the portions that are to be the sources of the transistors in the active regions 31 in the chip A through vias. The output lines 26 in the BM0 layer are connected to the portions that are to be the drains of the transistors in the active regions 31 in the chip A through vias.

With this configuration example, also, effects similar to those in the IO cell described above can be obtained. Note that, in this configuration example, also, power lines and output lines in a layer further below the BM2 layer may be formed in the chip B.

This configuration example is also applicable to layouts to be described later.

### Output Transistor P1

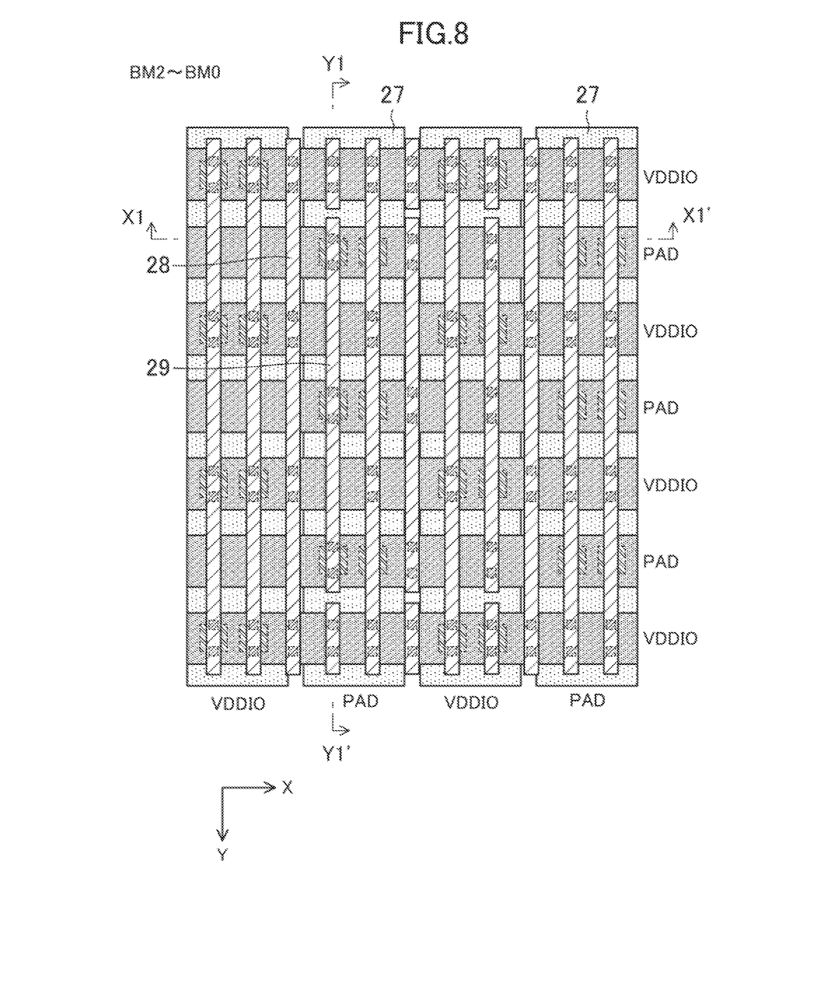

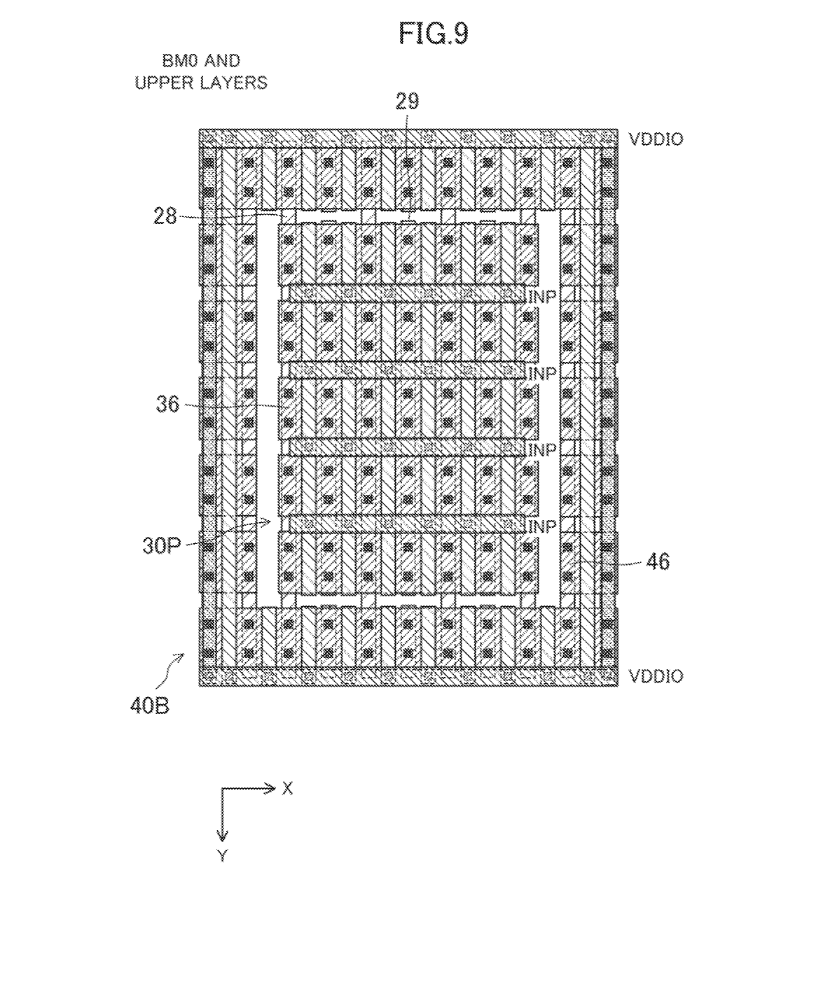

FIGS. 8 and 9 are plan views showing details of the layout of the output transistor P1 in FIG. 3. FIG. 8 shows a structure of the BM0 to BM2 layers, and FIG. 9 shows a structure of the BM0 layer and layers above the BM0 layer.

In the layout of FIGS. 8 and 9, in comparison with the layout of FIGS. 4 and 5, the conductivity type of active regions 36 in an output transistor part 30P is p-type, and the conductivity type of active regions 46 in a guard ring part 40B is n-type. Also, in the active regions 36, the power supply voltage supplied to the portions that are to be the source of the transistor P1 is VDDIO, and the signal given to the gate of the transistor P1 is INP. Since the layout of FIGS. 8 and 9 can be easily understood from the description on the layout of FIGS. 4 and 5, detailed description thereof is omitted here.

Note that output lines 27 in the BM2 layer continue with the output lines 22 for the output transistor N1 in the BM2 layer.

The output transistor part 30P including the transistor P1 connected between the power supply VDDIO and the external output terminal PAD has the active regions 36 forming the channel, source, and drain of the transistor P1. The active regions 36 have nanosheets as the channel. Power lines 28 and output lines 29 are placed in an interconnect layer on the back side of the transistor P1 so as to overlap the active regions 36 in planar view. The power lines 28 are connected to the lower faces of portions that are to be the source of the transistor P1 in the active regions 36 through vias, and the output lines 29 are connected to the lower faces of portions that are to be the drain of the transistor P1 in the active regions 36 through vias. It is therefore possible to pass a large current to the output terminal without the need to widen the layout area.

### ESD Protection Diode 1a

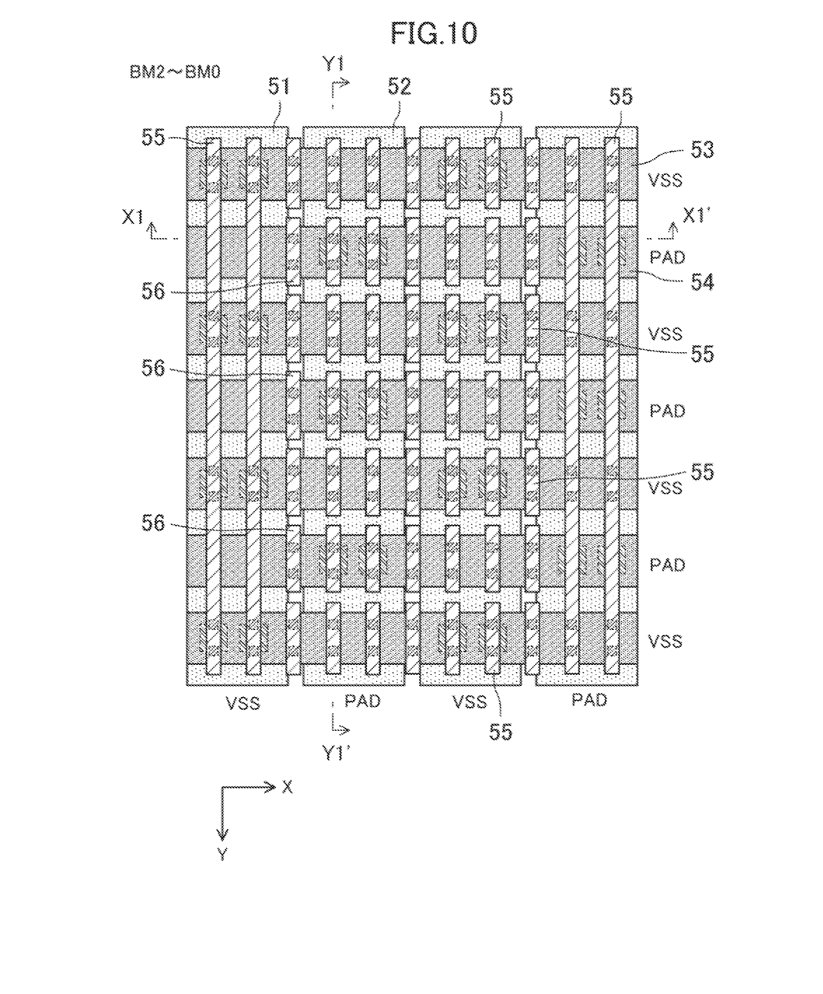

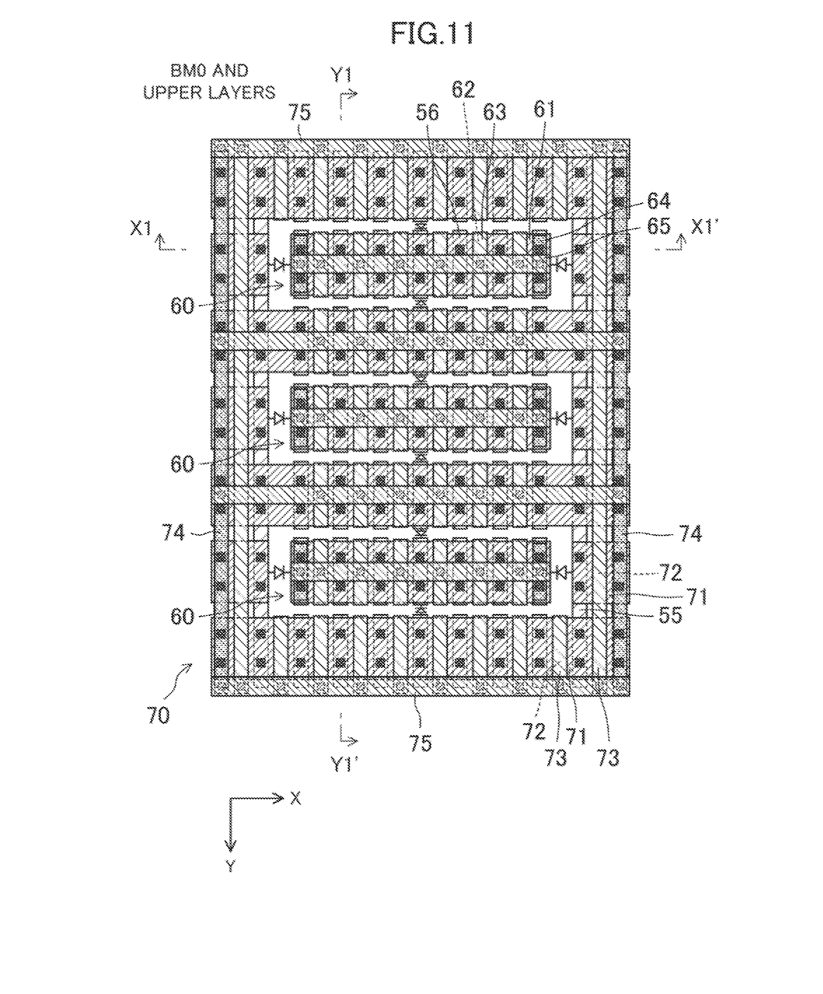

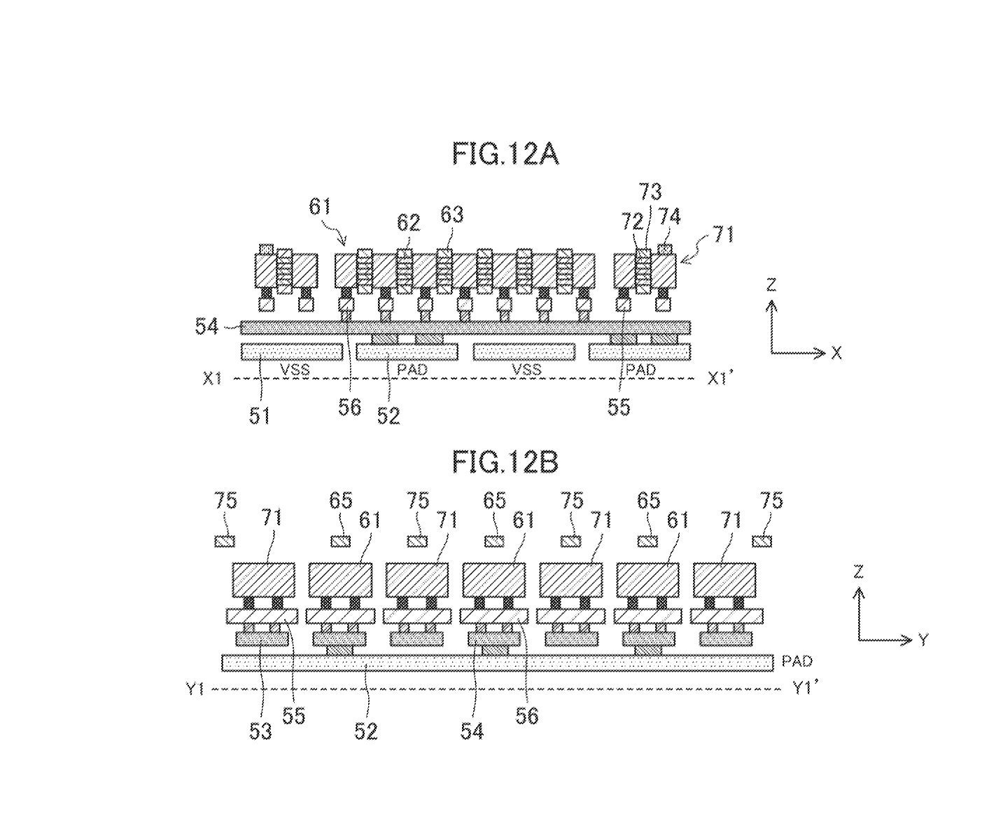

FIGS. 10 and 11 are plan views showing details of the layout of the ESD protection diode 1a in FIG. 3. FIG. 10 shows a structure of the BM0 to BM2 layers, and FIG. 11 shows a structure of the BM0 layer and layers above the BM0 layer. FIGS. 12A-12B are cross-sectional views of the layout of FIGS. 10 and 11, where FIG. 12A shows a cross-sectional structure taken along line X1-X1’ and FIG. 12B shows a cross-sectional structure taken along line Y1-Y1’.

As shown in FIG. 11, a cathode part 60 is formed in the upper, center, and lower portions of the figure, and an anode part 70 is formed to surround the cathode part 60.

As shown in FIG. 10, in the BM2 layer, power lines 51 and output lines 52 extending in the Y direction are placed. The power lines 51 supply the power supply voltage VSS, and the output lines 52 are connected to the external output terminal PAD. The power lines 51 and the output lines 52 are placed with the minimum spacing among them under constraints in the manufacturing processes.

In the BM1 layer, power lines 53 and output lines 54 extending in the X direction are placed. The power lines 53 are connected to the power lines 51 in the BM2 layer through vias, and the output lines 54 are connected to the output lines 52 in the BM2 layer through vias. The power lines 53 and the output lines 54 are placed with the minimum spacing among them under constraints in the manufacturing processes.

In the BM0 layer, power lines 55 and output lines 56 extending in the Y direction are placed. The power lines 55 are connected to the power lines 53 in the BM1 layer through vias. The power lines 55 are formed in the anode part 70. The output lines 56 are connected to the output lines 54 in the BM1 layer through vias. The output lines 56 are formed in the cathode part 60.

In the cathode part 60, n-type active regions 61 extending in the X direction are formed. Each active region 61 includes six nanosheets 62. Each nanosheet 62 has a structure of three sheets lying one above another and extends in the X direction. The active regions 61 however do not function as transistors.

In the active regions 61, portions sandwiching the nanosheets 62 (portions corresponding to the sources and drains of transistors) overlap the output lines 56 in the BM0 layer and are connected to the output lines 56 through vias.

In the active regions 61, gate interconnects 63 extending in the Y direction are formed. The gate interconnects 63 surround the peripheries of the nanosheets 62 in the Y direction and the Z direction through gate insulating films (not shown). The gate interconnects 63 however do not function as the gates of transistors. The gate interconnects 63 are connected to the active regions 61 through local interconnects 64 and M0 interconnects 65.

In the anode part 70, p-type active regions 71 are formed. Each active region 71 includes nanosheets 72. Each nanosheet 72 has a structure of three sheets lying one above another and extends in the X direction. The active regions 71 however do not function as transistors.

In the active regions 71, portions sandwiching the nanosheets 72 (portions corresponding to the sources and drains of transistors) overlap the power lines 55 in the BM0 layer in planar view and are connected to the power lines 55 through vias.

In the active regions 71, gate interconnects 73 extending in the Y direction are formed. The gate interconnects 73 surround the peripheries of the nanosheets 72 in the Y direction and the Z direction through gate insulating films (not shown). The gate interconnects 73 however do not function as the gates of transistors. The gate interconnects 73 are connected to the active regions 71 through local interconnects 74 and M0 interconnects 75. That is, the potential of the gate interconnects 73 is fixed to VSS.

Having the configuration described above, the following effects are obtained. Only the VSS-supply power lines and the output lines connected to the external output terminal PAD are placed as the interconnects formed on the back side of the active regions 61 and 71 constituting the ESD protection diode 1a. Also, in the BM1 layer and the BM2 layer, the power lines and the output lines are laid to the maximum extent. Therefore, interconnect resistance can be reduced, and thus the characteristics and performance of the ESD protection diode 1a can be improved.

Also, the power lines and the output lines in the BM0 layer are connected to the active regions 61 and 71 constituting the ESD protection diode 1a only through vias. Therefore, the resistance value can be reduced, and thus the characteristics and performance of the ESD protection diode 1a can be improved.

As described above, the ESD protection diode 1a connected between the power supply VSS and the external output terminal PAD includes the p-type active regions 71 constituting the anode part 70 and the n-type active regions 61 constituting the cathode part 60. The active regions 61 have the nanosheets 62, and the active regions 71 have the nanosheets 72. The power lines 55 and the output lines 56 are placed in the interconnect layer on the back side of the active regions 61 and 71. The power lines 55 are connected to the lower faces of the portions sandwiching the nanosheets 72 in the active regions 71 through vias, and the output lines 56 are connected to the lower faces of the portions sandwiching the nanosheets 62 in the active regions 61 through vias. It is therefore possible to improve the characteristics and performance of the ESD protection diode 1a without the need to widen the layout area.

The power lines 51, 53, and 55 and the output lines 52, 54, and 56 may be formed in a plurality of interconnect layers.

Moreover, an interconnect layer may be formed further below the BM2 layer to form backside lines. In this case, it is preferable to change the directions in which the lines extend alternately, such as that lines extend in the X direction in a BM3 layer and extend in the Y direction in a BM4 layer, for example.

### ESD Protection Diode 1b

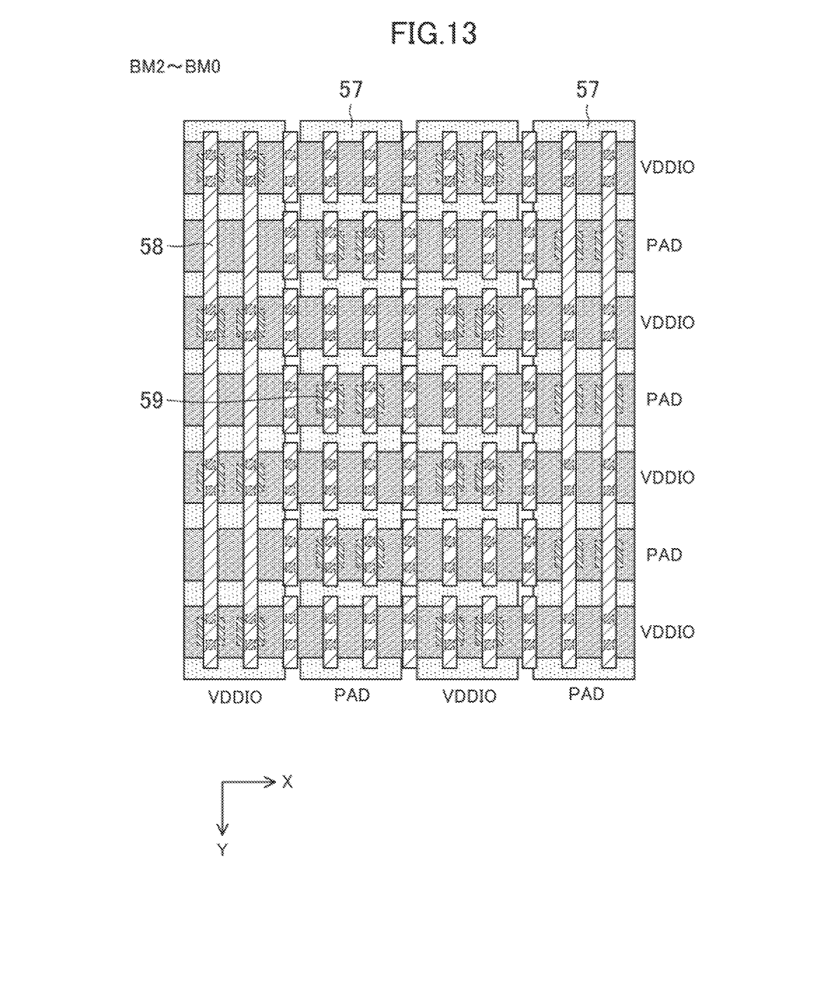

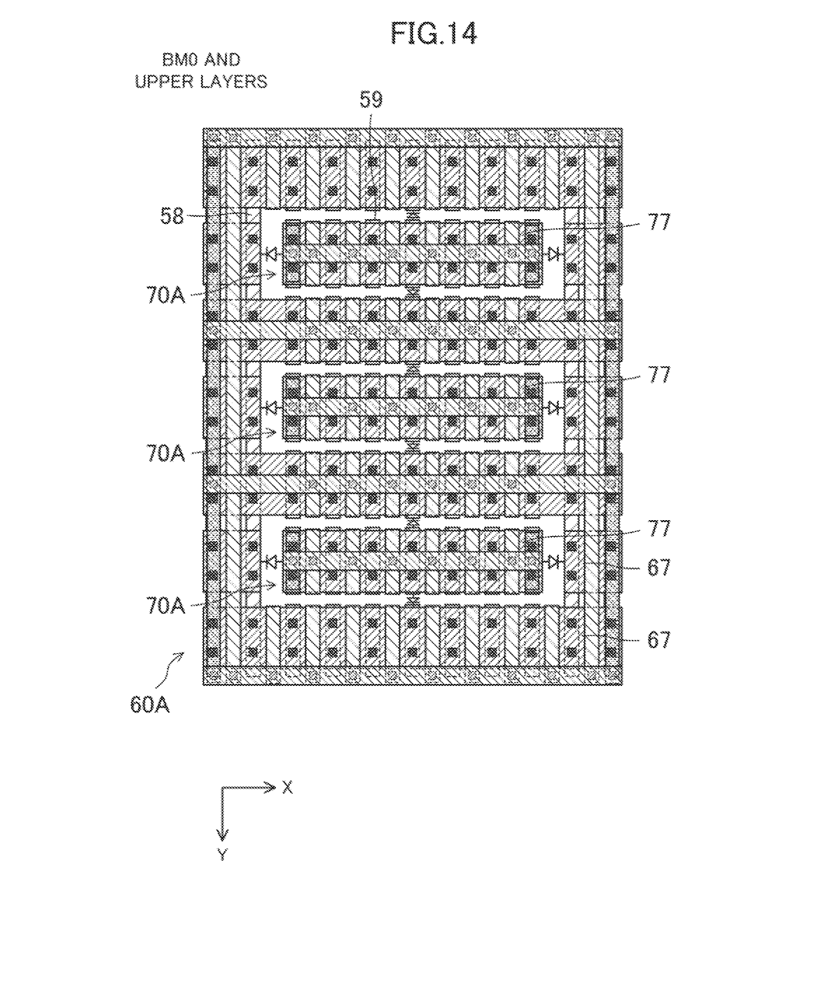

FIGS. 13 and 14 are plan views showing details of the layout of the ESD protection diode 1b in FIG. 3. FIG. 13 shows a structure of the BM0 to BM2 layers, and FIG. 14 shows a structure of the BM0 layer and layers above the BM0 layer.

In the layout of FIGS. 13 and 14, in comparison with the layout of FIGS. 10 and 11, the positions of the anode part and the cathode part are changed with each other. That is, an anode part 70A is formed in the upper, center, and lower portions of the figure, and a cathode part 60A is formed to surround the anode part 70A. The conductivity type of active regions 77 in the anode part 70A is p-type, and the conductivity type of the active regions 67 in the cathode part 60A is n-type. Also, the power supply voltage supplied to portions sandwiching nanosheets in the active regions 67 in the cathode part 60A is VDDIO.

Since the layout of FIGS. 13 and 14 can be easily understood from the description on the layout of FIGS. 10 and 11, detailed description thereof is omitted here.

Note that output lines 57 in the BM2 layer continue with the output lines 52 for the ESD protection diode 1a in the BM2 layer. Also, the output lines 52 and 57 continue with the output lines 22 and 27 for the output transistors N1 and P1 in the BM2 layer.

The ESD protection diode 1b connected between the power supply VDDIO and the external output terminal PAD includes the n-type active regions 67 constituting the cathode part 60A and the p-type active regions 77 constituting the anode part 70A. Power lines 58 and output lines 59 are placed in the interconnect layer on the back side of the active regions 67 and 77. The power lines 58 are connected to the lower faces of the portions sandwiching the nanosheets in the active regions 67 through vias, and the output lines 59 are connected to the lower faces of the portions sandwiching the nanosheets in the active regions 77 through vias. It is therefore possible to improve the characteristics and performance of the ESD protection diode 1b without the need to widen the layout area.

### Second Embodiment

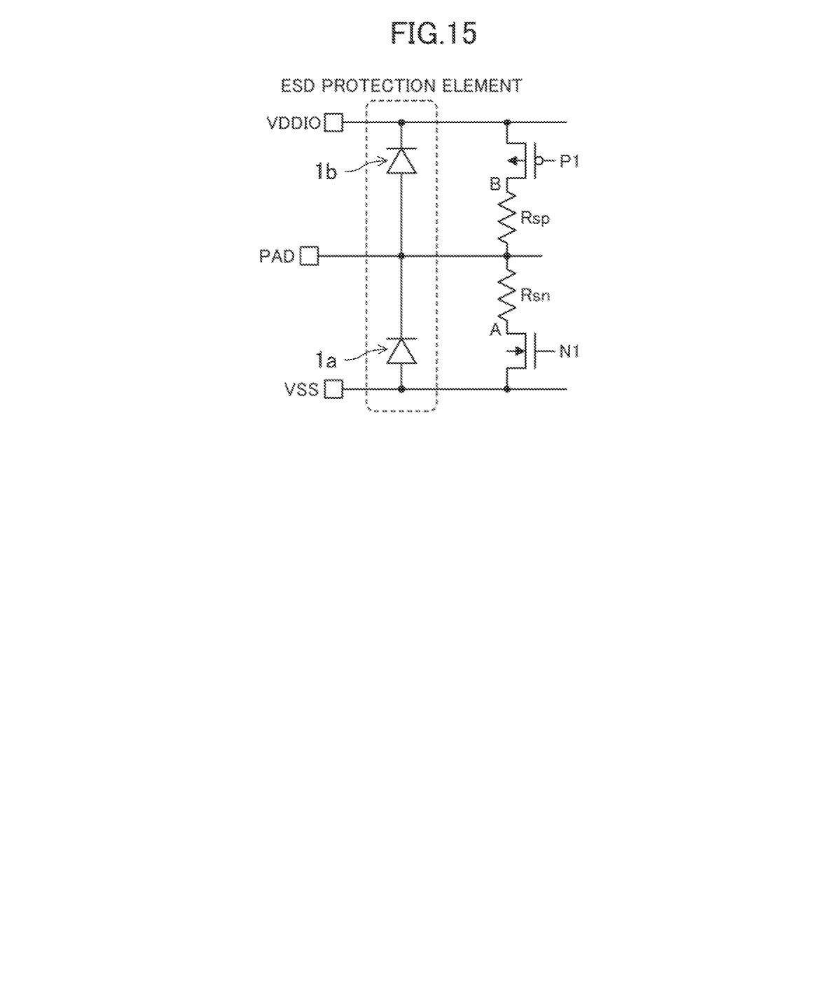

FIG. 15 is a circuit configuration diagram of an output circuit included in the IO cell 10 in the second embodiment. Note that, although an actual output circuit includes circuit elements other than those shown in FIG. 15, such elements are omitted in FIG. 15.

The output circuit shown in FIG. 15 includes protective resistances Rsn and Rsp, in addition to the external output terminal PAD, the output transistors P1 and N1, and the ESD protection diodes 1a and 1b included in the output circuit 11 shown in FIG. 2.

The output transistor P1 is connected to VDDIO at its source and to the external output terminal PAD at its drain through the protective resistance Rsp. The output transistor N1 is connected to VSS at its source and to the external output terminal PAD at its drain through the protective resistance Rsn. In this embodiment, the protective resistances Rsp and Rsn are each constituted by a plurality of resistor elements formed in an interconnect layer that is formed in the back end of line (BEOL: interconnect process). Note that the node between the output transistor N1 and the protective resistance Rsn is herein called node A and the node between the output transistor P1 and the protective resistance Rsp is called node B.

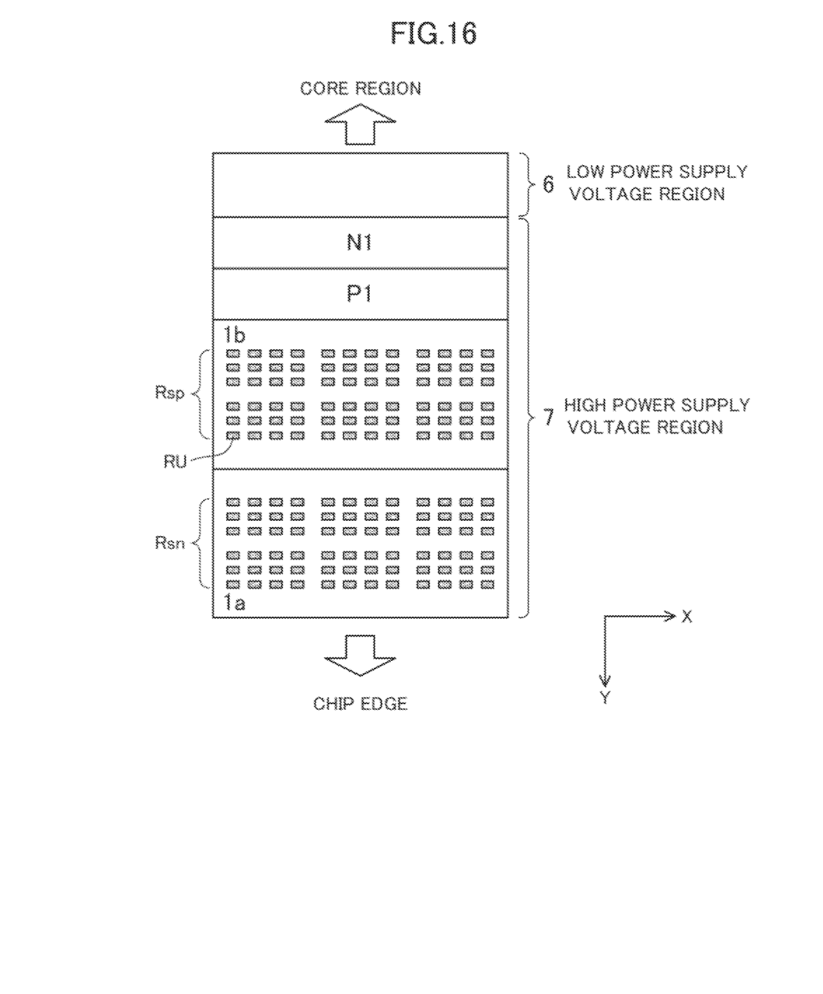

FIG. 16 shows an overview example of the layout of the IO cell in this embodiment. In the high power supply voltage region 7, resistor elements RU are arranged in an array in the X-Y directions above areas in which the ESD protection diode 1a and the ESD protection diode 1b are placed. The resistor elements RU are formed in a layer above the M0 interconnect layer. The resistor elements RU placed above the ESD protection diode 1b are mutually connected, to constitute the protective resistance Rsp. The resistor elements RU placed above the ESD protection diode 1a are mutually connected, to constitute the protective resistance Rsn.

The protective resistance Rsp is connected between the external output terminal PAD and the node B, and interconnects corresponding to the node B extend from the area in which the protective resistance Rsp is formed to the area in which the output transistor P1 is placed. The protective resistance Rsn is connected between the external output terminal PAD and the node A, and interconnects corresponding to the node A extend from the area in which the protective resistance Rsn is formed to the area in which the output transistor N1 is placed.

Note that the positions of the protective resistances Rsp and Rsn in planar view are not limited to those shown in FIG. 16.

### Output Transistors N1 and P1

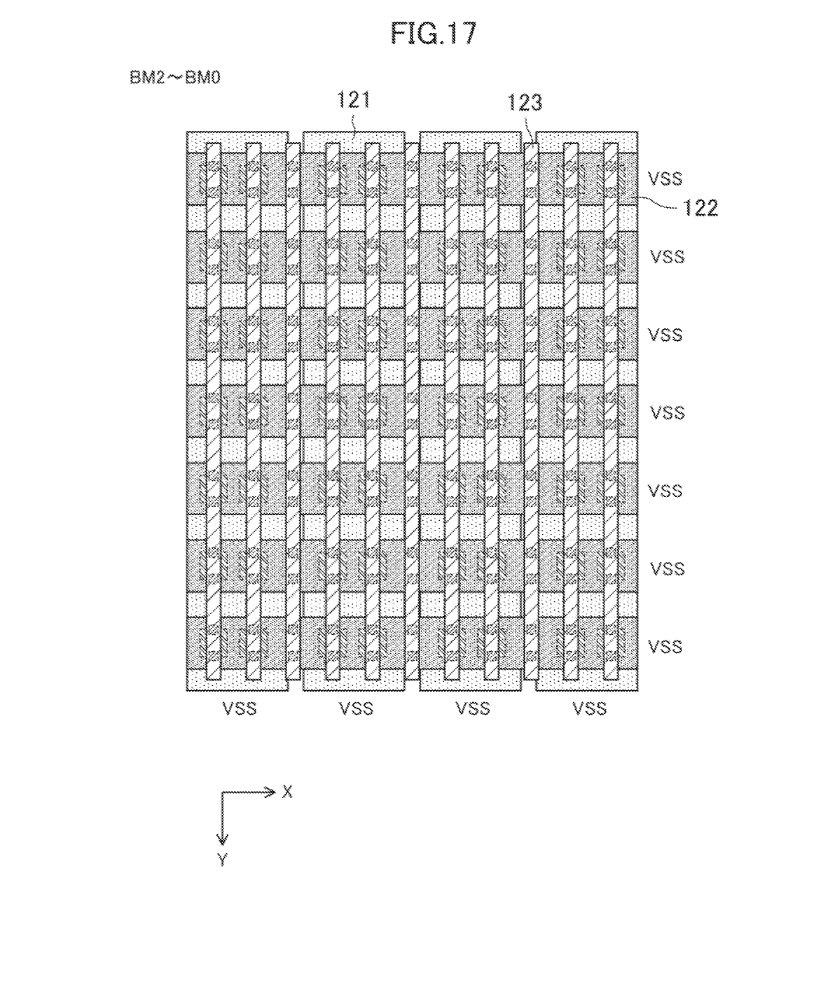

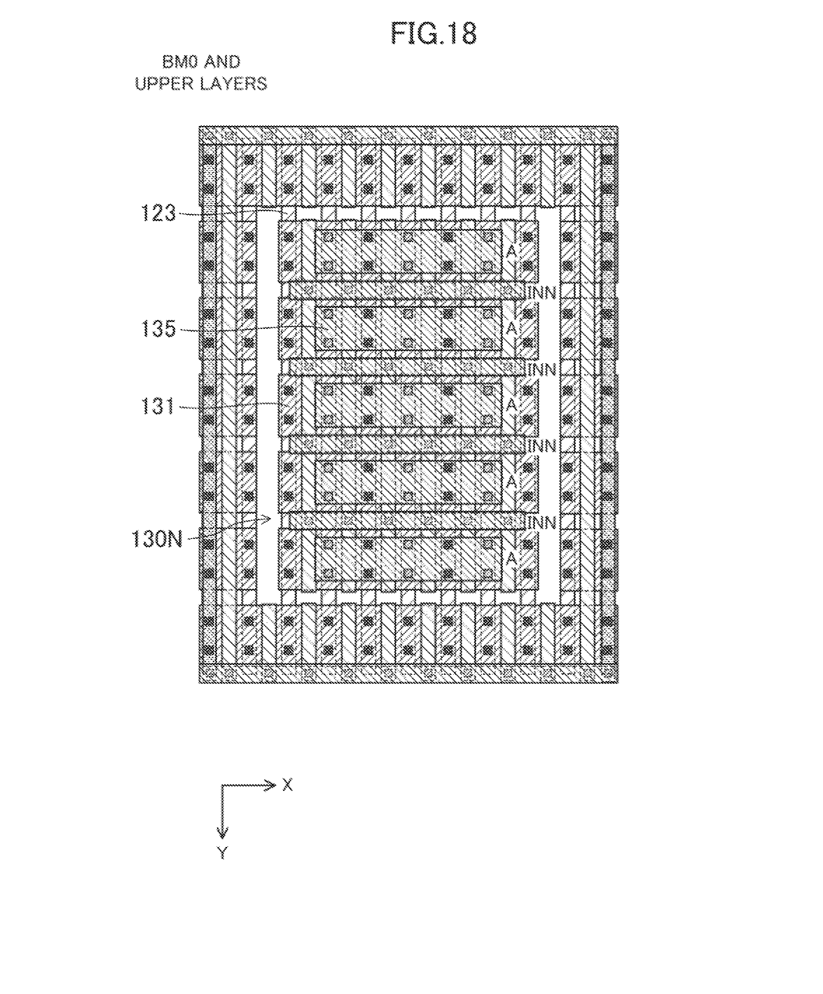

FIGS. 17 and 18 are plan views showing details of the layout of the output transistor N1 in FIG. 16. FIG. 17 shows a structure of the BM0 to BM2 layers, and FIG. 18 shows a structure of the BM0 layer and layers above the BM0 layer. Note that description may be omitted or simplified for configurations similar to those in the layout shown in FIGS. 4 and 5.

As shown in FIG. 17, in the BM2 layer, power lines 121 extending in the Y direction are placed. The power lines 121 supply the power supply voltage VSS. The power lines 121 are placed with the minimum spacing among them under constraints in the manufacturing processes.

In the BM1 layer, power lines 122 extending in the X direction are placed. The power lines 122 are connected to the power lines 121 in the BM2 layer through vias, and supply the power supply voltage VSS. The power lines 122 are placed with the minimum spacing among them under constraints in the manufacturing processes.

In the BM0 layer, power lines 123 extending in the Y direction are placed. The power lines 123 are connected to the power lines 122 in the BM1 layer through vias, and supply the power supply voltage VSS.

That is, the interconnects placed in the BM0 to BM2 layers are all VSS-supply power lines.

As shown in FIG. 18, in an output transistor part 130N, n-type active regions 131 extending in the X direction are formed. In the active regions 131, portions that are to be the source of the transistor N1 overlap the power lines 123 in the BM0 layer in planar view, and are connected to the power lines 123 through vias. On the other hand, portions that are to be the drain of the transistor N1 in the active regions 131 are connected to interconnects 135 formed in the M0 interconnect layer through vias. The interconnects 135 correspond to the node A. The interconnects 135 are connected to the protective resistance Rsn through interconnects and vias (not shown). That is, the protective resistance Rsn is connected, at one end, to the portions that are to be the drain of the transistor N1 in the active regions 131. The other end of the protective resistance Rsn is connected to an output line (not shown) connected to the external output terminal PAD.

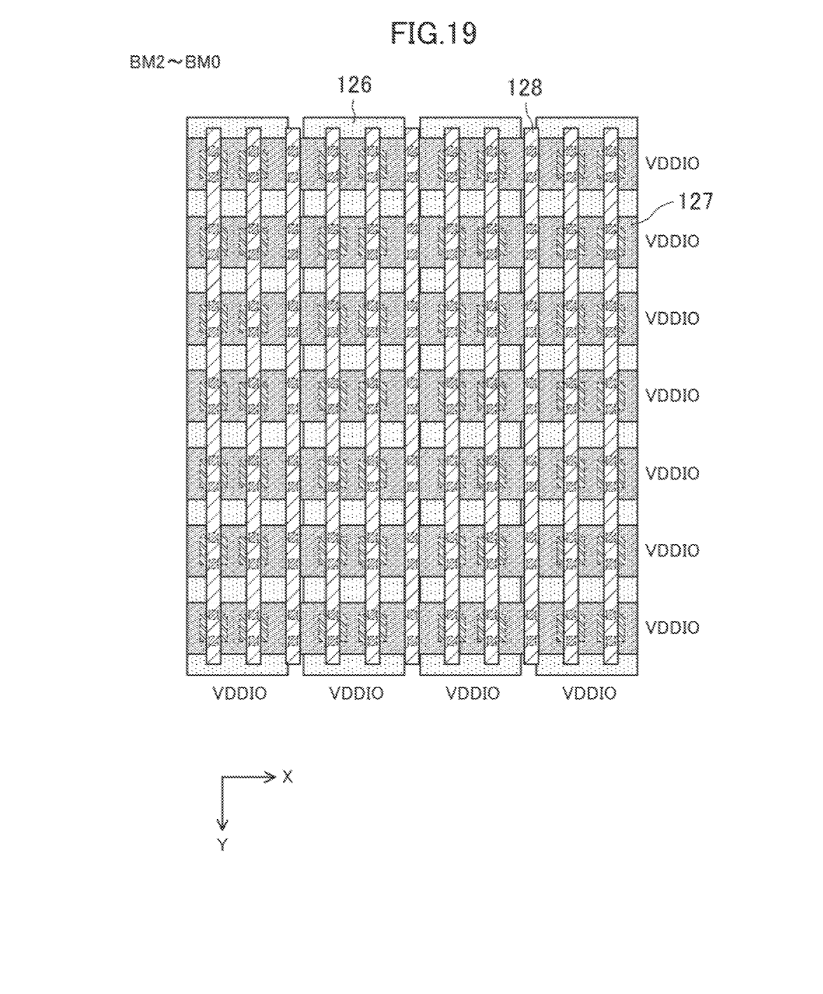

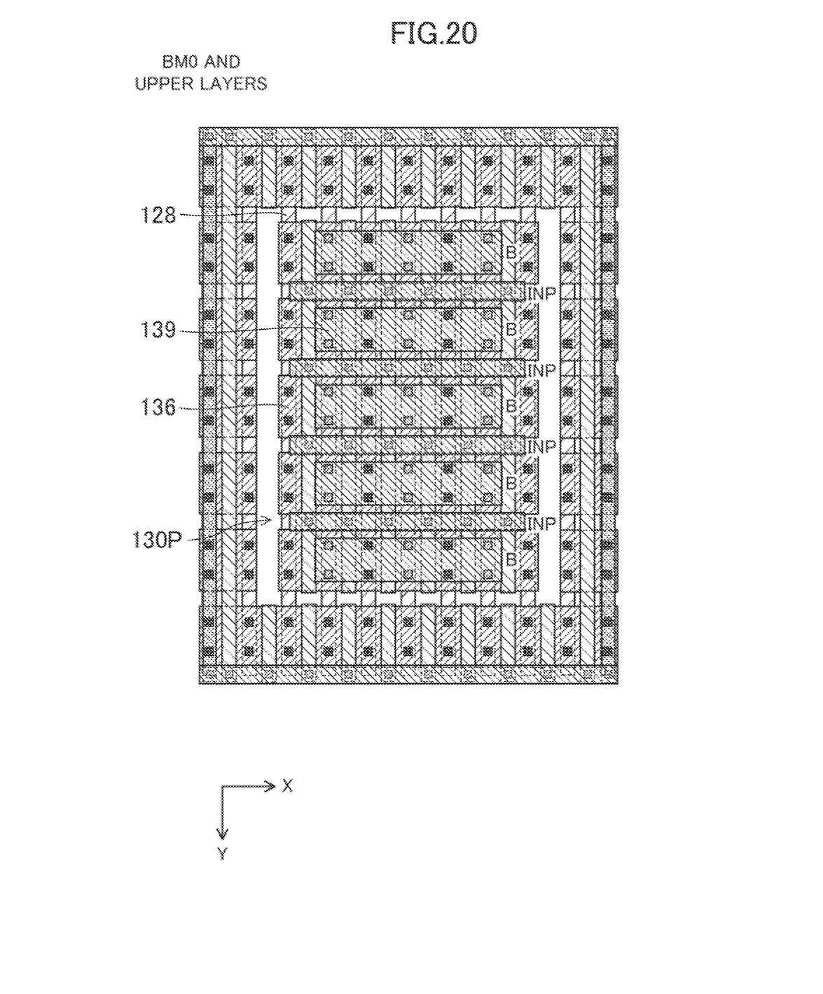

FIGS. 19 and 20 are plan views showing details of the layout of the output transistor P1 in FIG. 16. FIG. 19 shows a structure of the BM0 to BM2 layers, and FIG. 20 shows a structure of the BM0 layer and layers above the BM0 layer. Note that description may be omitted or simplified for configurations similar to those in the layout shown in FIGS. 8 and 9.

As shown in FIG. 19, in the BM2 layer, power lines 126 extending in the Y direction are placed. The power lines 126 supply the power supply voltage VDDIO. The power lines 126 are placed with the minimum spacing among them under constraints in the manufacturing processes.

In the BM1 layer, power lines 127 extending in the X direction are placed. The power lines 127 are connected to the power lines 126 in the BM2 layer through vias, and supply the power supply voltage VDDIO. The power lines 127 are placed with the minimum spacing among them under constraints in the manufacturing processes.

In the BM0 layer, power lines 128 extending in the Y direction are placed. The power lines 128 are connected to the power lines 127 in the BM1 layer through vias, and supply the power supply voltage VDDIO.

That is, the interconnects placed in the BM0 to BM2 layers are all VDDIO-supply power lines.

As shown in FIG. 20, in an output transistor part 130P, p-type active regions 136 extending in the X direction are formed. In the active regions 136, portions that are to be the source of the transistor P1 overlap the power lines 128 in the BM0 layer in planar view, and are connected to the power lines 128 through vias. On the other hand, portions that are to be the drain of the transistor P1 in the active regions 136 are connected to interconnects 139 formed in the M0 interconnect layer. The interconnects 139 correspond to the node B. The interconnects 139 are connected to the protective resistance Rsp through interconnects and vias (not shown). That is, the protective resistance Rsp is connected, at one end, to the portions that are to be the drain of the transistor P1 in the active regions 136. The other end of the protective resistance Rsp is connected to an output line (not shown) connected to the external output terminal PAD.

Having the configuration described above, the following effects are obtained. Only the power lines supplying VSS and VDDIO are placed as the interconnects formed on the back side of the transistors. Also, in the BM1 layer and the BM2 layer, the power lines are laid to the maximum extent. It is therefore possible to pass a larger current than in the configuration shown in the first embodiment, and also further reduce interconnect resistance.

As described above, the output transistor part 130N including the transistor N1 connected between the power supply VSS and the node A has the active regions 131 forming the channel, source, and drain of the transistor N1. The active regions 131 have nanosheets as the channel. The power lines 123 are placed in the interconnect layer on the back side of the transistor N1, and connected to the lower faces of the portions that are to be the source of the transistor N1 in the active regions 131 through vias. The protective resistance Rsn connected between the external output terminal PAD and the node A is formed in a layer located above the active regions 131, and connected to the portions that are to be the drain of the transistor N1 in the active regions 131 at one end and to the output line connected to the external output terminal PAD at the other end.

Also, the output transistor part 130P including the transistor P1 connected between the power supply VDDIO and the node B has the active regions 136 forming the channel, source, and drain of the transistor P1. The active regions 136 have nanosheets as the channel. The power lines 128 are placed in the interconnect layer on the back side of the transistor P1, and connected to the lower faces of the portions that are to be the source of the transistor P1 in the active regions 136 through vias. The protective resistance Rsp connected between the external output terminal PAD and the node B is formed in a layer located above the active regions 136, and connected to the portions that are to be the drain of the transistor P1 in the active regions 136 at one end and to the output line connected to the external output terminal PAD at the other end.

Having the configuration described above, it is possible to pass a large current to the output terminal without the need to widen the layout area.

### ESD Protection Diodes 1a and 1b

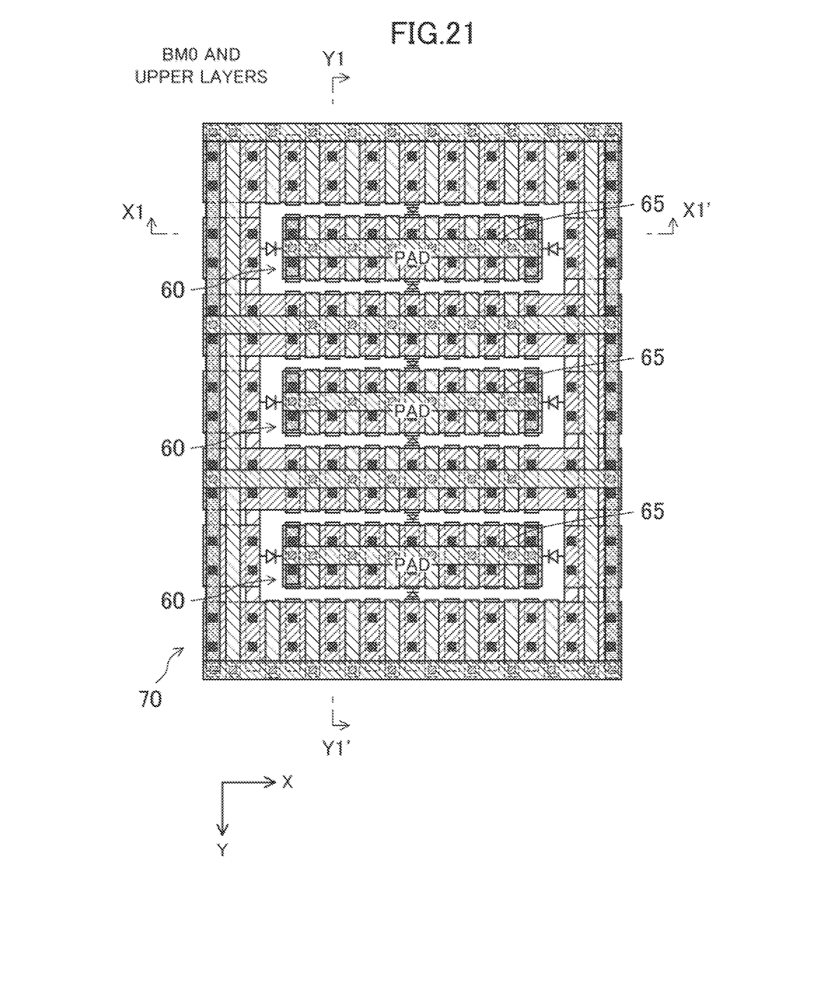

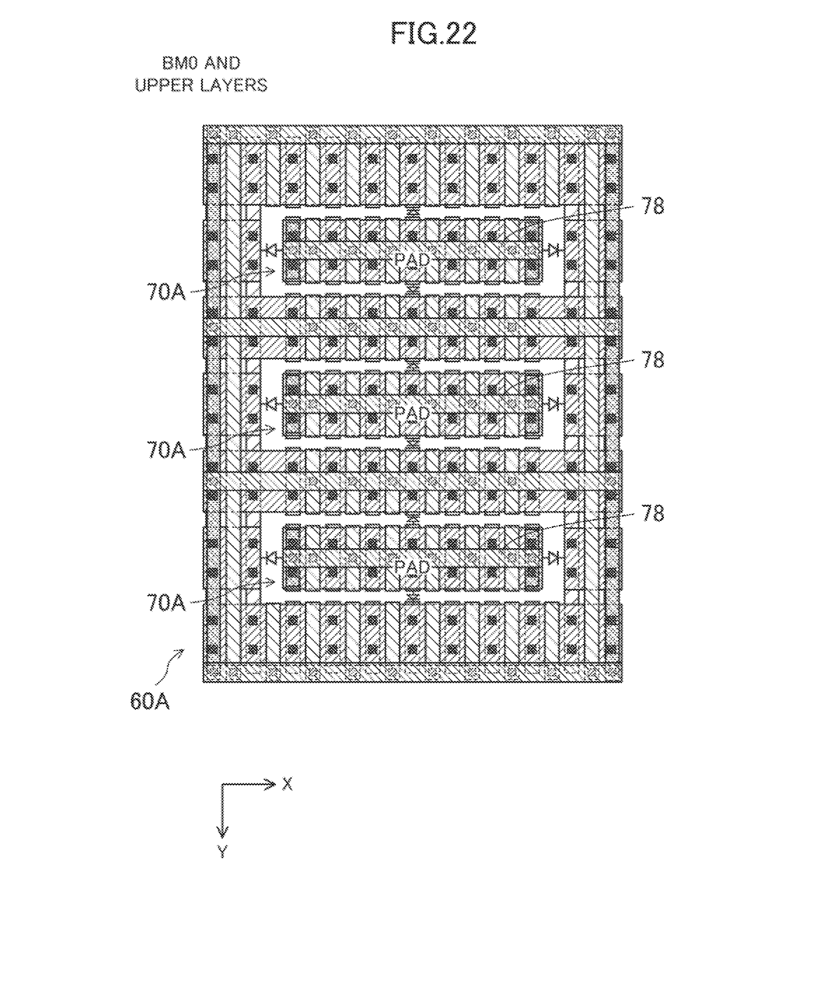

FIG. 21 is a plan view showing details of the layout of the ESD protection diode 1a in FIG. 16, showing a structure of the BM0 interconnect layer and layers above the BM0 layer. FIG. 22 is a plan view showing details of the layout of the ESD protection diode 1b in FIG. 16, showing a structure of the BM0 interconnect layer and layers above the BM0 layer.

The layout structures of the ESD protection diodes 1a and 1b in this embodiment are the same as the layout structures of the ESD protection diodes 1a and 1b in the first embodiment shown in FIGS. 10 to 14.

FIG. 21 shows the same configuration as FIG. 11, and the word “PAD” is given to the M0 interconnects 65 in the cathode part 60. The M0 interconnects 65 are connected to the protective resistance Rsn through interconnects and vias (not shown). FIG. 22 shows the same configuration as FIG. 14, and the word “PAD” is given to M0 interconnects 78 in the anode part 70A. The M0 interconnects 78 are connected to the protective resistance Rsp through interconnects and vias (not shown).

In this embodiment, also, similar effects to those in the ESD protection diodes 1a and 1b in the first embodiment are obtained. Moreover, since it is unnecessary to provide a region for connecting the protective resistances Rsn and Rsp with the external output terminal PAD, increase in area is avoided.

Note that, in this embodiment, also, the other configuration example described in the first embodiment is applicable.

### Alteration

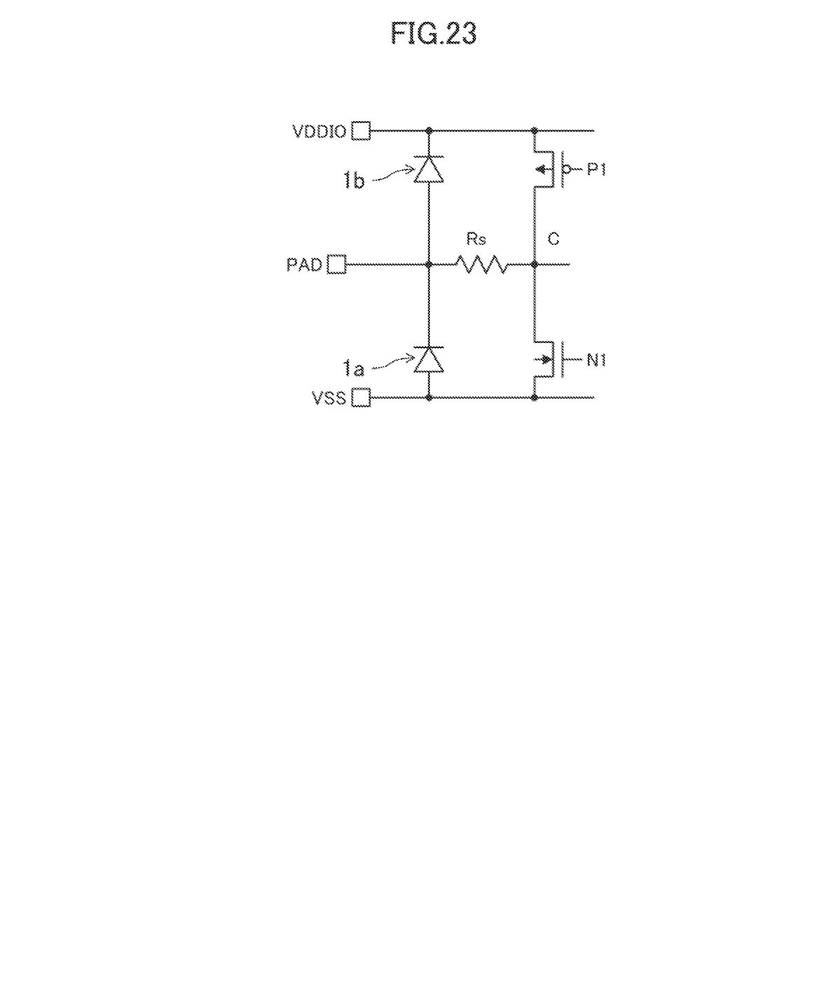

FIG. 23 is a circuit configuration diagram of an output circuit according to an alteration of the second embodiment. The circuit configuration of FIG. 23 is similar to the circuit configuration of FIG. 15 in the second embodiment, except for the position of insertion of a protective resistance. That is, in the output circuit of FIG. 23, a protective resistance Rs is provided in place of the protective resistances Rsn and Rsp in FIG. 15. In FIG. 23, the drains of the output transistors P1 and N1 are mutually connected, and the protective resistance Rs is provided between the external output terminal PAD and the drains of the output transistors P1 and N1. Note that the node between the drains of the output transistors P1 and N1 and the protective resistance Rs is herein called node C.

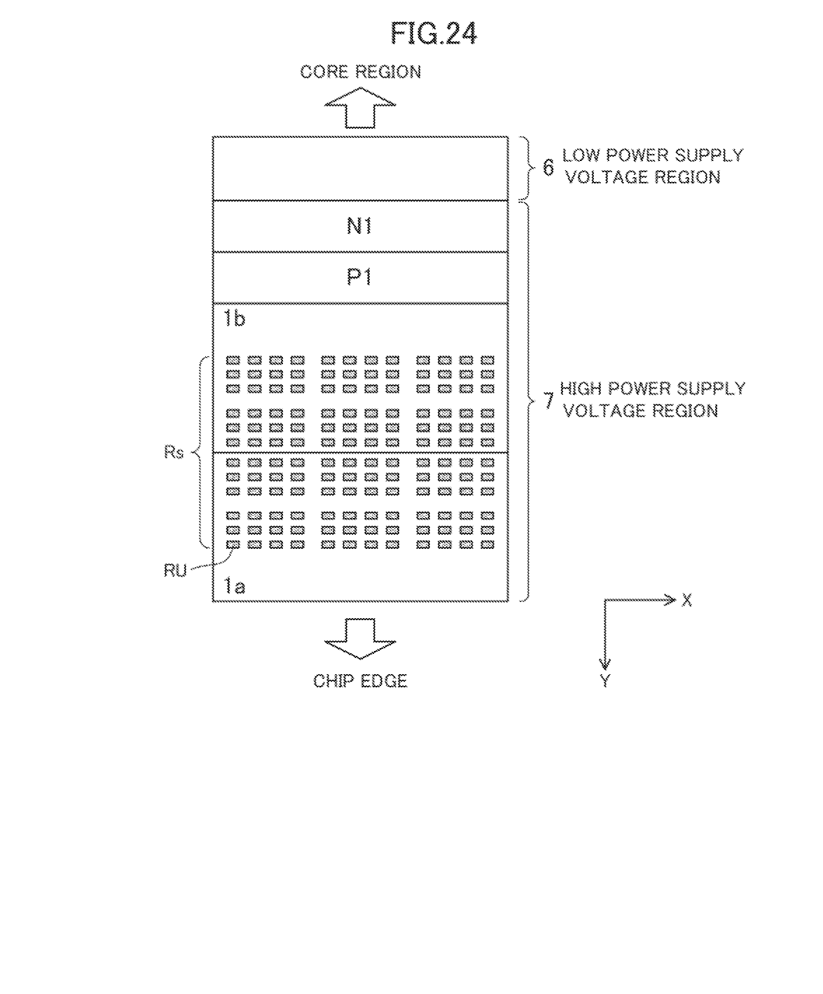

FIG. 24 shows an overview example of the layout of an IO cell in this alteration. Resistor elements RU placed above the ESD protection diodes 1a and 1b are mutually connected, to constitute the protective resistance Rs.

In this alteration, both the M0 interconnects 135 corresponding to the node A in the output transistor N1 and the M0 interconnects 139 corresponding to the node B in the output transistor P1 in the second embodiment correspond to the node C. The layout structures of the output transistors N1 and P1 and the ESD protection diodes 1a and 1b are the same as those in the second embodiment, and similar effects to those in the second embodiment are obtained.

While both the p-type transistor and the n-type transistor are one-stage transistors in the output circuit in the above embodiments, the configuration is not limited to this. For example, transistors of a plurality of stages such as two stages and three stages may be serially connected. Also, the output circuit in the above embodiments may be an input/output circuit including an input circuit.

According to the present disclosure, in a semiconductor integrated circuit device having a configuration in which interconnects are laid right under transistors, a circuit that passes a large current and an ESD protection circuit can be implemented. The present disclosure is therefore useful for improvement of the performance of a System on Chip (SoC).

1. A semiconductor integrated circuit device, comprising:
a first output transistor part including a first transistor of a first conductivity type connected between a first power supply supplying a first power supply voltage and an output terminal;
a first power line supplying the first power supply voltage; and
an output line connected to the output terminal,
wherein
the first output transistor part includes
a first active region of the first conductivity type forming a channel, source, and drain of the first transistor, and having a nanosheet as the channel,
the first power line is placed in an interconnect layer located on a back side of the first transistor so as to overlap the first active region in planar view, and connected to a lower face of a portion that is to be the source of the first transistor in the first active region through a via, and
the output line is placed in the same interconnect layer as the first power line so as to overlap the first active region in planar view, and connected to a lower face of a portion that is to be the drain of the first transistor in the first active region through a via.

2. The semiconductor integrated circuit device of claim 1, further comprising:
a guard ring part formed around the first output transistor part,
wherein
the guard ring part includes
a second active region of a second conductivity type having a second nanosheet, and
the first power line is connected to lower faces of portions sandwiching the second nanosheet in the second active region through vias.

3. The semiconductor integrated circuit device of claim 2, wherein
the guard ring part includes
a gate interconnect formed to surround the second nanosheet, and
the gate interconnect is supplied with the first power supply voltage.

4. The semiconductor integrated circuit device of claim 1, wherein
the first power line and the output line are formed in an interconnect layer provided in a first semiconductor chip in which the first active region is formed.

5. The semiconductor integrated circuit device of claim 1, wherein
the first power line and the output line are formed in an interconnect layer provided in a second semiconductor chip bonded to a back of a first semiconductor chip in which the first active region is formed.

6. A semiconductor integrated circuit device, comprising:
an electrostatic discharge (ESD) protection diode connected between a first power supply supplying a first power supply voltage and an output terminal;
a first power line supplying the first power supply voltage; and
an output line connected to the output terminal,
wherein
the ESD protection diode includes
a first active region of a first conductivity type constituting one terminal out of an anode and a cathode, and having a first nanosheet, and
a second active region of a second conductivity type constituting the other terminal out of the anode and the cathode, and having a second nanosheet,
the first power line is placed in an interconnect layer located on a back side of the first and second active regions so as to overlap the first active region in planar view, and connected to lower faces of portions sandwiching the first nanosheet in the first active region through vias, and
the output line is placed in the same interconnect layer as the first power line so as to overlap the second active region in planar view, and connected to lower faces of portions sandwiching the second nanosheet in the second active region through vias.

7. The semiconductor integrated circuit device of claim 6, further comprising:
a first interconnect placed in an interconnect layer located above the first and second active regions so as to overlap the second active region in planar view; and
a resistor element formed in a layer above the first interconnect,
wherein
the resistor element is connected to upper faces of portions sandwiching the second nanosheet in the second active region through the first interconnect.

8. The semiconductor integrated circuit device of claim 6, wherein
the first power line and the output line are formed in an interconnect layer provided in a first semiconductor chip in which the first active region is formed.

9. The semiconductor integrated circuit device of claim 6, wherein
the first power line and the output line are formed in an interconnect layer provided in a second semiconductor chip bonded to a back of a first semiconductor chip in which the first active region is formed.

10. A semiconductor integrated circuit device, comprising:
a first output transistor part including a first transistor of a first conductivity type connected between a first power supply supplying a first power supply voltage and a first node;
a protective resistance connected between an output terminal and the first node; and
a first power line supplying the first power supply voltage,
wherein
the first output transistor part includes
a first active region of the first conductivity type forming a channel, source, and drain of the first transistor, and having a nanosheet as the channel,
the first power line is placed in an interconnect layer located on a back side of the first transistor so as to overlap the first active region in planar view, and connected to a lower face of a portion that is to be the source of the first transistor in the first active region through a via, and
the protective resistance is formed in a layer above the first active region, and is connected to a portion that is to be the drain of the first transistor in the first active region at one end and to an output line connected to the output terminal at the other end.

11. The semiconductor integrated circuit device of claim 10, further comprising:
a guard ring part formed around the first output transistor part,
wherein
the guard ring part includes
a second active region of a second conductivity type having a second nanosheet, and
the first power line is connected to lower faces of portions sandwiching the second nanosheet in the second active region through vias.

12. The semiconductor integrated circuit device of claim 11, wherein
the guard ring part includes
a gate interconnect formed to surround the second nanosheet, and
the gate interconnect is supplied with the first power supply voltage.

13. The semiconductor integrated circuit device of claim 10, wherein
the first power line and the output line are formed in an interconnect layer provided in a first semiconductor chip in which the first active region is formed.

14. The semiconductor integrated circuit device of claim 10, wherein
the first power line and the output line are formed in an interconnect layer provided in a second semiconductor chip bonded to a back of a first semiconductor chip in which the first active region is formed.
